(19) United States
(12) Patent Application Publication
(10) Pub. No.: US 2026/0344424 A1
(43) Pub. Date: Oct. 29, 2026

(54) PACKAGE LID INCLUDING A MULTI-LAYER STRUCTURE FOR HEAT DISSIPATION AND METHODS OF FORMING THE SAME

(71) Applicant: Taiwan Semiconductor Manufacturing Company Limited, Hsinchu (TW)

(72) Inventors: Wen-Yi LIN, New Taipei City (TW); Kuang-Chun LEE, New Taipei City (TW); Chien-Chen LI, Hsinchu (TW); Chien-Li KUO, Hsinchu City (TW); Kuo-Chio LIU, Hsinchu City (TW)

(21) Appl. No.: 19/735,665

(22) Filed: Jul. 9, 2026

Related U.S. Application Data
(62) Division of application No. 18/114,362, filed on Feb. 27, 2023.

(51) Int. Cl. H10W 40/25; H10W 40/22; H10W 70/02; H10W 76/15; H10W 72/00; H10W 72/30; H10W 74/15; H10W 90/00

(52) U.S. Cl. CPC H10W 40/254; H10W 40/226; H10W 70/02; H10W 76/15; H10W 72/07354; H10W 72/347; H10W 72/877; H10W 74/15; H10W 90/724; H10W 90/734; H10W 90/736

(57) ABSTRACT

An embodiment semiconductor package structure may include a package substrate, a semiconductor die coupled to the package substrate, and a package lid attached to the package substrate and covering the semiconductor die. The package lid may include a top portion having a spatially varying thermal conductivity that is greater in a first region than in a second region. The first region may include a multi-layer structure including a metal/diamond composite material supported by a copper layer. The metal/diamond composite material may include a silver/diamond, copper/diamond, or aluminum/diamond material and may have a thermal conductivity that is within a range from 600 W/m·K to 900 W/m·K and a coefficient of thermal expansion that is in a second range from 5 ppm/ °C to 10 ppm/ °C. The package lid may have an effective coefficient of thermal expansion that is in a range from 14.5 ppm/ °C to 17 ppm/ °C.

### RELATED APPLICATIONS

This application is a divisional application of U.S. Application Serial No. 18/114,362 entitled “Package Lid Including a Multi-layer Structure for Heat Dissipation and Methods of Forming the Same,” filed on Feb. 27, 2023, the entire contents of which are incorporated herein in their entirety by reference for all purposes.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers over a semiconductor substrate, and patterning the various material layers using lithography and etching to form circuit components and elements thereon. Dozens or hundreds of integrated circuits are typically manufactured on a single semiconductor wafer, and individual dies on the wafer are singulated by sawing between the integrated circuits along scribe lines. The individual dies are typically packaged separately, in multi-chip modules, or in other types of packaging, for example. Issues related to thermal management and heat removal from semiconductor packages present challenges requiring new structures and techniques for efficient thermal energy management.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a semiconductor device along line AA’ in FIG. 1B, according to various embodiments.

FIG. 1B is a horizontal cross-sectional view of the semiconductor device along line BB’ in FIG. 1A, according to various embodiments.

FIG. 2A is a vertical cross-sectional view of semiconductor package structure having a hot spot in a central region during operation.

FIG. 2B is a vertical cross-sectional view of an embodiment semiconductor package having a package lid that includes a multi-layer structure including a first material having a first thermal conductivity and a second material having a second thermal conductivity, according to various embodiments.

FIG. 3A is a top view of an intermediate structure that may be used in the formation of a package lid, according to various embodiments.

FIG. 3B is a vertical cross-sectional view of the intermediate structure of FIG. 3A, according to various embodiments.

FIG. 4A is a top view of a further intermediate structure that may be used in the formation of a package lid, according to various embodiments.

FIG. 4B is a vertical cross-sectional view of the intermediate structure of FIG. 4A, according to various embodiments.

FIG. 5A is a top view of a further intermediate structure that may be used in the formation of a package lid, according to various embodiments.

FIG. 5B is a vertical cross-sectional view of the intermediate structure of FIG. 5A, according to various embodiments.

FIG. 6A is a top view of a further intermediate structure that may be used in the formation of a package lid, according to various embodiments.

FIG. 6B is a vertical cross-sectional view of the intermediate structure of FIG. 6A, according to various embodiments.

FIG. 7A is a top view of a package lid having a multi-layer structure, according to various embodiments.

FIG. 7B is a vertical cross-sectional view of the package lid of FIG. 7A, according to various embodiments.

FIG. 8A is a top view of a further package lid having a multi-layer structure, according to various embodiments.

FIG. 8B is a vertical cross-sectional view of the package lid of FIG. 8A, according to various embodiments.

FIG. 9A is a top view of a further package lid having a multi-layer structure, according to various embodiments.

FIG. 9B is a vertical cross-sectional view of the package lid of FIG. 9A, according to various embodiments.

FIG. 10A is a top view of a further package lid having a multi-layer structure including two spatially separated portions, according to various embodiments.

FIG. 10B is a vertical cross-sectional view of the package lid of FIG. 10A, according to various embodiments.

FIG. 11A is a top view of a further package lid having a multi-layer structure including four spatially separated portions, according to various embodiments.

FIG. 11B is a vertical cross-sectional view of the package lid of FIG. 11A, according to various embodiments.

FIG. 12A is a top view of a further package lid having a multi-layer structure including a single second material portion having a polygon shape, according to various embodiments.

FIG. 12B is a vertical cross-sectional view of the package lid of FIG. 12A, according to various embodiments.

FIG. 13A is a top view of a further package lid having a multi-layer structure including a single second material portion having a curved shape, according to various embodiments.

FIG. 13B is a vertical cross-sectional view of the package lid of FIG. 13A, according to various embodiments.

FIG. 14A is a top view of a further package lid having a multi-layer structure including three spatially separated portions each having a curved shape, according to various embodiments.

FIG. 14B is a vertical cross-sectional view of the package lid of FIG. 14A, according to various embodiments.

FIG. 15A is a top view of a further package lid having a tri-layer structure, according to various embodiments.

FIG. 15B is a vertical cross-sectional view of the package lid of FIG. 15A, according to various embodiments.

FIG. 16A is a vertical cross-sectional view of an intermediate structure that may be used in the formation of a semiconductor package structure, according to various embodiments.

FIG. 16B is a vertical cross-sectional view of a further intermediate structure that may be used in the formation of a semiconductor package structure, according to various embodiments.

FIG. 16C is a vertical cross-sectional view of a further intermediate structure that may be used in the formation of a semiconductor package structure, according to various embodiments.

FIG. 16D is a vertical cross-sectional view of a further intermediate structure that may be used in the formation of a semiconductor package structure, according to various embodiments.

FIG. 16E is a vertical cross-sectional view of a semiconductor package structure including a package lid having a spatially varying thermal conductivity that is greater in a first region than in a second region, according to various embodiments.

FIG. 17A is a vertical cross-sectional view of an initial configuration of an apparatus that may be used to form a metal/diamond composite, according to various embodiments.

FIG. 17B is a vertical cross-sectional view of a further configuration of an apparatus that may be used to form a metal/diamond composite, according to various embodiments.

FIG. 17C is a vertical cross-sectional view of a further configuration of an apparatus that may be used to form a metal/diamond composite, according to various embodiments.

FIG. 17D is a vertical cross-sectional view of a further configuration of an apparatus that may be used to form a metal/diamond composite, according to various embodiments.

FIG. 18A is a side view of a bulk metal/diamond composite material, formed by a gas pressure infiltration process, according to various embodiments.

FIG. 18B is a side view of a plurality of sections of the metal/diamond composite material cut from the bulk metal/diamond composite material of FIG. 18A, according to various embodiments.

FIG. 18C is a side view of an apparatus that may be used to polish one of the sections of the metal/diamond composite material of FIG. 18B, according to various embodiments.

FIG. 18D is a side view of a finished piece of the metal/diamond composite material after a plating operation has been performed, according to various embodiments.

FIG. 19 is a flowchart illustrating operations of a method of forming a package lid for a semiconductor package structure, according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Typically, in a semiconductor package, a number of semiconductor integrated circuit (IC) dies (i.e., “chips”) may be mounted onto a common substrate. The semiconductor package typically includes a housing that encloses the IC dies to protect the IC dies from damage. The housing may also provide heat dissipation from the semiconductor package. In some cases, the semiconductor package may include a package lid that may include a thermally-conductive material (e.g., a metal or metal alloy, such as copper). The package lid may be located over the IC dies. Heat generated by the IC dies may be transferred from the upper surfaces of the IC dies into the package lid and may be ultimately dissipated to the environment. The heat may optionally be dissipated through a heat sink that may be attached to or may be integrally formed with the lid or through other components of the semiconductor package. Package lids made of a single metal (e.g., copper), however, may not be configured to efficiently remove heat in situations in which the heat sources generate a non-uniform spatial distribution of heat flux. In such situations, hot spots may be generated that may cause damage to semiconductor devices.

Various embodiments disclosed herein may further provide a package lid having a spatially varying thermal conductivity that is greater in certain regions corresponding to regions having increased heat flux. Various embodiments may include a multi-layer structure that incorporates a metal/diamond composite material supported by a copper layer. Such embodiment package lids may exhibit increased heat dissipation efficiency and reduced thermal-expansion induced warpage and other deformations in contrast to package lids made of a single material.

Various embodiment semiconductor package structures may include a package substrate, a semiconductor die coupled to the package substrate, and a package lid attached to the package substrate and covering the semiconductor die. The package lid may include a top portion having a spatially varying thermal conductivity that is greater in a first region than in a second region. At least a portion of the first region may be positioned to be overlapping with a location of the semiconductor die in a plan view. The first region may include a first material having a first thermal conductivity and a second material having a second thermal conductivity such that the second material is supported by the first material, such that the second thermal conductivity is within a first range from approximately 600 W/m·K to approximately 900 W/m·K.

In a further embodiment, a package lid for a semiconductor package structure may include a top portion configured to cover a semiconductor die and a plurality of side structures configured to attach to a package substrate and to support the top portion at a predetermined distance above the package substrate. The top portion may include a multi-layer structure including a first material having a first thermal conductivity and a second material having a second thermal conductivity, and the second thermal conductivity may be within a range from approximately 600 W/m·K to approximately 900 W/m·K. The second material may include a coefficient of thermal expansion (CTE) that is in a first range from approximately 5 ppm/ ̊C to approximately 10 ppm/ ̊C, and the package lid may have an effective coefficient of thermal expansion that is in a second range from approximately 14.5 ppm/ ̊C to approximately 17 ppm/ ̊C. In various embodiments, the second material may include a silver/diamond, a copper/diamond, or an aluminum/diamond composite material.

An embodiment method of forming a package lid for a semiconductor package structure may include forming an inner cavity in a slab of a first material such that the inner cavity is bounded by an internal surface of a top portion and at least partially bounded by internal surfaces of a plurality of side structures. The inner cavity may be configured to cover a semiconductor die and the plurality of side structures may be configured to attach to a package substrate and to support the top portion at a predetermined distance above the package substrate. The method may further include forming an outer cavity in an external surface of the top portion and securing a second material to the first material within the outer cavity so that the second material is bonded to at least one surface of the outer cavity. The second material may have a thermal conductivity that is within a range from approximately 600 W/m·K to approximately 900 W/m·K.

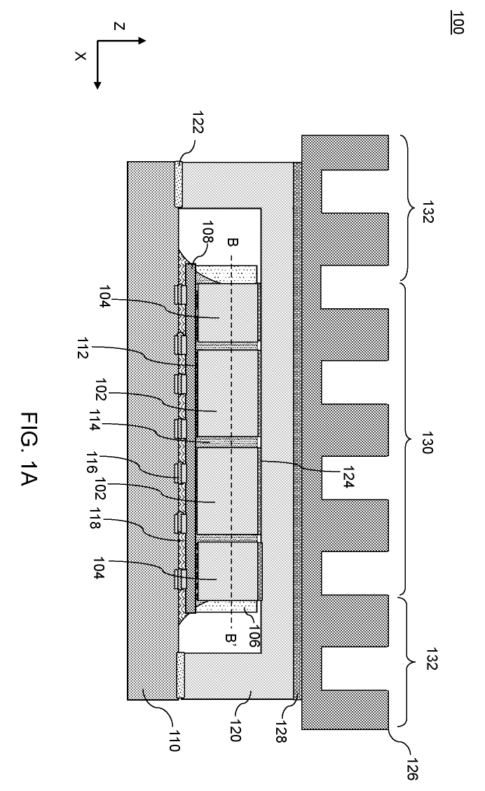

FIG. 1A is a vertical cross-sectional view of a semiconductor package structure 100, according to various embodiments. FIG. 1B is a horizontal cross-sectional view of the semiconductor package structure 100 defined by a horizontal plane indicated by the line B – B’ in FIG. 1A. The view of FIG. 1A is defined by a vertical plane indicated by the line A – A’ in FIG. 1B. The semiconductor package structure 100 may include one or more integrated circuit (IC) semiconductor devices. For example, the semiconductor package structure 100 may include a plurality of first semiconductor dies 102 and a plurality of second semiconductor dies 104. In various embodiments, each first semiconductor die 102 may be configured as a three-dimensional device, such as a three-dimensional integrated circuit (3DIC), a system-on-chip (SoC) device, or a system-on-integrated-circuit (SoIC) device.

Each of the first semiconductor dies 102 may be formed by placing chips on a semiconductor wafer level. These three-dimensional devices may provide improved integration density and other advantages, such as faster speeds and higher bandwidths, due to a decreased length of interconnects between the stacked chips. In some embodiments, one of the first semiconductor dies 102 may also be referred to as a “first die stack.” In some embodiments, each of the first semiconductor dies 102 may be dies or chips, such as logic dies, power management dies, voltage regulator dies, etc.

In the semiconductor package structure 100 of FIGS. 1A and 1B, the plurality of first semiconductor dies 102 includes four first die stacks (e.g., see FIG. 1B), each of which may be configured as a SoC device. In various embodiments, the first semiconductor dies 102 may be adjacent to one another and may be located in a central portion of the semiconductor package structure 100. The semiconductor package structure 100 may further include one or more second semiconductor dies 104. In some embodiments, the one or more second semiconductor dies 104 may be three-dimensional IC semiconductor devices and may also be referred to as “second die stacks.” In some embodiments, the second semiconductor dies 104 may each be a semiconductor memory device, such as a high bandwidth memory (HBM) device.

In the embodiment shown in FIGS. 1A and 1B, the plurality of second semiconductor dies 104 includes eight second die stacks (e.g., see FIG. 1B), each of which may be an HBM device. The second semiconductor dies 104 may be located on a periphery around the first semiconductor dies 102, as shown in FIG. 1B. A molding material 106, which may include an epoxy-based material, may be located around the periphery of the first semiconductor dies 102 and the second semiconductor dies 104. Although the embodiment illustrated in FIGS. 1A and 1B includes four (4) first semiconductor dies 102 and eight (8) second semiconductor dies 104, greater or fewer die stacks may be included in semiconductor package structures in other embodiments.

Referring again to FIG. 1A, the first semiconductor dies 102 and the second semiconductor dies 104 may be mounted on an interposer 108. In some embodiments, the interposer 108 may be an organic interposer including a polymer dielectric material (e.g., a polyimide material) having a plurality of metal interconnect structures extending therethrough. In other embodiments, the interposer 108 may be a semiconductor interposer, such as a silicon interposer, having a plurality of interconnect structures (e.g., through-silicon vias) extending therethrough. Other suitable configurations for the interposer are contemplated within the scope of the disclosure. The interposer 108 may include a plurality of conductive bonding pads (not shown) on upper and lower surfaces of the interposer 108 and a plurality of conductive interconnects (not shown) extending through the interposer 108 between the upper and lower bonding pads of the interposer 108.

The conductive interconnects may distribute and route electrical signals between IC semiconductor devices (e.g., first semiconductor dies 102 and second semiconductor dies 104) and a package substrate 110. Thus, the interposer 108 may also be referred to as redistribution layers (RDLs). A plurality of first metal bumps 112, such as micro-bumps, may electrically connect conductive bonding pads on the bottom surfaces of the first semiconductor dies 102 and second semiconductor dies 104 to the conductive bonding pads on the upper surface of the interposer 108.

In one non-limiting embodiment, first metal bumps 112 in the form of micro-bumps may include a plurality of first metal stacks, such as a plurality of Cu-Ni-Cu stacks, located on the bottom surfaces of the first semiconductor dies 102 and the second semiconductor dies 104. A corresponding plurality of second metal stacks (e.g., Cu-Ni-Cu stacks) may be located on the upper surface of the interposer 108. A solder material, such as tin (Sn), may be located between respective first and second metal stacks to electrically connect the first semiconductor dies 102 and the second semiconductor dies 104 to the interposer 108. Other suitable materials for the first metal bumps 112 are within the contemplated scope of this disclosure.

A first underfill material portion 114 may be provided in the spaces surrounding the first metal bumps 112 and between the bottom surfaces of the first semiconductor dies 102, the second semiconductor dies 104, and the upper surface of the interposer 108. The first underfill material portion 114 may also be provided in the spaces laterally separating adjacent die stacks (i.e., first semiconductor dies 102 and second semiconductor dies 104) of the semiconductor package structure 100. Thus, the first underfill material portion 114 may extend over side surfaces of the first semiconductor dies 102 and/or the second semiconductor dies 104, as shown in FIG. 1A. In various embodiments, the first underfill material portion 114 may include an epoxy-based material, which may include a composite of resin and filler materials. Other underfill materials are within the contemplated scope of this disclosure.

The interposer 108 may be located on a package substrate 110, which may provide mechanical support for the interposer 108 and the IC semiconductor devices (e.g., first semiconductor dies 102 and second semiconductor dies 104) that are mounted thereon. The package substrate 110 may include a suitable material, such as a semiconductor material (e.g., a semiconductor wafer, such as a silicon wafer), a ceramic material, an organic material (e.g., a polymer and/or thermoplastic material), a glass material, combinations thereof, etc. Other suitable substrate materials are within the contemplated scope of this disclosure.

In various embodiments, the package substrate 110 may include a plurality of conductive bonding pads in an upper surface of the package substrate 110. A plurality of second metal bumps 116, such as C4 solder bumps, may electrically connect conductive bonding pads on the bottom surface of the interposer 108 to the conductive bonding pads on the upper surface of the package substrate 110. In various embodiments, the second metal bumps 116 may include a suitable solder material, such as tin (Sn).

A second underfill material portion 118 may be provided in the spaces surrounding the second metal bumps 116 and between the bottom surface of the interposer 108 and the upper surface of the package substrate 110. In various embodiments, the second underfill material portion 118 may include an epoxy-based material, which may include a composite of resin and filler materials. The second underfill material portion 118 may be the same material as the first underfill material portion 114 or may be a different material.

A package lid 120 may be disposed over the upper surfaces of the IC semiconductor devices (e.g., the first semiconductor dies 102 and the second semiconductor dies 104). The package lid 120 may also laterally surround the IC semiconductor devices (e.g., the first semiconductor dies 102 and the second semiconductor dies 104) such that the first semiconductor dies 102 and the second semiconductor dies 104 are fully-enclosed by the combination of the package substrate 110 and the package lid 120. In other embodiments, the package lid 120 may only partially enclose the first semiconductor dies 102 and the second semiconductor dies 104. For example, the package lid 120 may have one or more vent holes (not shown) to allow moisture and vapors to escape the package lid 120.

The package lid 120 may be attached to an upper surface of the package substrate 110 with an adhesive 122. In various embodiments, the adhesive 122 may be a thermally-conductive adhesive. Other suitable adhesive materials are within the contemplated scope of this disclosure. In some embodiments, the package lid 120 may be integrally formed or may include pieces. For example, the package lid 120 may include a ring portion (not shown) surrounding the first semiconductor dies 102 and the second semiconductor dies 104, a cover portion covering the ring portion, the first semiconductor dies 102, and the second semiconductor dies 104, and an adhesive (not shown) connecting the cover portion to the ring portion.

In some embodiments, a first thermal interface material 124 may be disposed between an upper surface of each of the IC semiconductor devices (e.g., the first semiconductor dies 102 and the second semiconductor dies 104) and an interior surface of the package lid 120. In various embodiments, the first thermal interface material 124 may include a gel-type thermal interface material having a relatively high thermal conductivity. Other suitable materials for the first thermal interface material 124 are within the contemplated scope of this disclosure. In some embodiments, the first thermal interface material 124 may include a single thermal interface material piece covering both the first semiconductor dies 102 and the second semiconductor dies 104, or two or more thermal interface material pieces corresponding to each of the first semiconductor dies 102 and the second semiconductor dies 104.

In some embodiments, a heat sink 126 may be provided on an upper surface of the package lid 120. The heat sink 126 may include fins or other features that may be configured to increase a surface area between the heat sink 126 and a cooling fluid, such as ambient air. In some embodiments, the heat sink 126 may be a separate component that may be attached to an upper surface of the package lid 120, as shown in FIG. 1A. Alternatively, the heat sink 126 may be integrally formed with the package lid 120. In embodiments in which the heat sink 126 is a separate component from the package lid 120, a second thermal interface material 128 may be located between the upper surface of the package lid 120 and a bottom surface of the heat sink 126. In various embodiments, the second thermal interface material 128 may include a gel-type thermal interface material having a relatively high thermal conductivity. Other suitable materials for the second thermal interface material 128 are within the contemplated scope of this disclosure. The heat sink 126 may include a suitable thermally-conductive material, such as a metal (e.g., copper) or metal alloy.

In various embodiments, a central region 130 of the semiconductor package structure 100 may be a region of the semiconductor package structure 100 that includes a relatively higher density of the one or more integrated circuit (IC) semiconductor devices, such as the first semiconductor dies 102 and the second semiconductor dies 104, as shown in FIGS. 1A and 1B. The semiconductor package structure 100 may include peripheral regions 132. Each of the peripheral regions 132 may be a region of the semiconductor package structure 100 that has a relatively lower density of integrated circuit (IC) semiconductor devices, for example, including a region that does not include any IC semiconductor devices.

In the embodiment of FIGS. 1A and 1B, excessive heat accumulation in the semiconductor package structure 100 may be more likely to occur in the central region 130 of the semiconductor package structure 100 that includes the highest density of IC semiconductor devices (e.g., the first semiconductor dies 102 and the second semiconductor dies 104) than in the peripheral regions 132 of the semiconductor package structure 100. This may be because the majority of the heat in the semiconductor package structure 100 is generated by the IC semiconductor devices (e.g., the first semiconductor dies 102 and the second semiconductor dies 104) in the central region 130 of the semiconductor package structure 100. As such, heat transfer through the package lid 120 may occur primarily along the vertical direction (i.e., the direction of the z-axis in FIG. 1A) rather than spreading horizontally through the semiconductor package structure 100 (i.e., along the x-axis and y-axis directions in FIGS. 1A and 1B). Thus, the portion of the package lid 120 overlying the IC semiconductor devices (102, 104) in the central region 130 of the semiconductor package structure 100 may be the hottest portion of the package lid 120 during operation of the semiconductor device.

The concentration of heat generating elements and the hottest portion of the package lid 120 being located in the central region 130 may result in overheating and damage to the semiconductor package structure 100 if the rate of heat loss from the central region 130 of the semiconductor package structure 100 is not sufficiently high. In practice, this means that the package lid 120 may include a material having a very high thermal conductivity, such as copper, which has a thermal conductivity of about 398 W/m·K. As development of semiconductor package structures progresses, however, the heat generated by increasingly more densely packaged IC components may demand new structures and methods for more efficient heat removal.

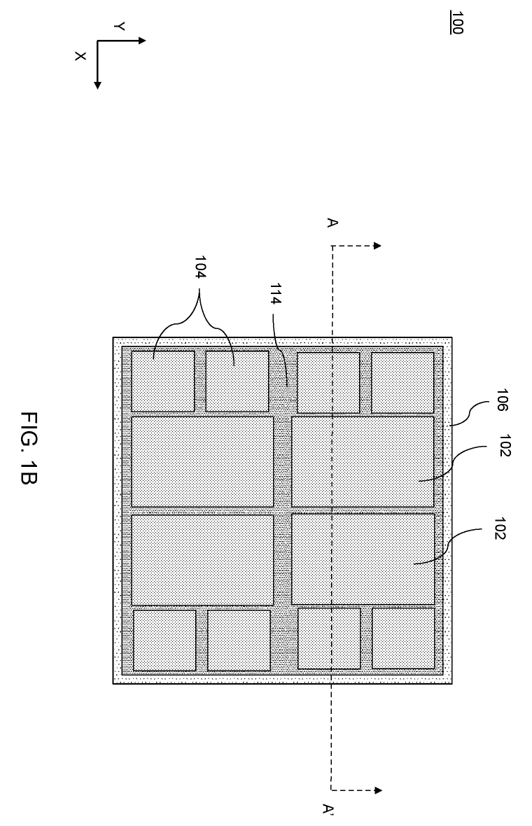

FIG. 2A is a vertical cross-sectional view of a semiconductor package structure 200a having a hot spot 202 in a central region 130 during operation, and FIG. 2B is an embodiment semiconductor package structure 200b having a more uniform distribution of heat flux, according to various embodiments. In this regard, the embodiment semiconductor package structure 200b may include a package lid 120b that includes a multi-layer (multi-material) structure 204 including a first material 206 having a first thermal conductivity and a second material 208 having a second thermal conductivity. The first material 206 may be a metal such as aluminum or copper that may have sufficient thermal conductivity to dissipate a lower heat flux such as may be generated in the peripheral regions 132 of the semiconductor package structure 200a. To accommodate a greater heat flux such as the heat flux shown in the central region 130 (e.g., see FIG. 2A), the second material 208 may be chosen to have a significantly larger thermal conductivity.

According to an embodiment, the second material 208 may be a material such as a metal/diamond composite in which diamond particles may be formed within a metal matrix. In various embodiments, the second material 208 may be a silver/diamond, a copper/diamond, or an aluminum/diamond composite material. A silver/diamond composite material may have a thermal conductivity that may be in a range from approximately 600 W/ m·K to approximately 900 W/m·K. The multi-layer structure 204 may have an effective thermal conductivity that is intermediate between the thermal conductivity of the first material 206 (e.g., 398 W/m·K) and the thermal conductivity of the second material 208 (e.g., 600 W/ m·K to approximately 900 W/ m·K). Further, the value of the effective thermal conductivity of the multi-layer structure 204 may be determined based on geometric considerations. For example, in some embodiments, the effective thermal conductivity of the multi-layer structure 204 may be a weighted average of the thermal conductivities of the first material 206 and the second material 208 based on relative volumes of the first material 206 and the second material 208, respectively.

The multi-layer structure 204 may have a width 210 that is vertically overlapping (e.g., when seen in a plan view) with a location of one or more of the first semiconductor dies 102 and the second semiconductor dies 104. The width 210 may be configured to optimize a heat flow pattern based on an estimated or measured heat flux that may be generated by the first semiconductor dies 102 and the second semiconductor dies 104. For example, the multi-layer structure 204 may have a width 210 that overlaps with all of the first semiconductor dies 102 and the second semiconductor dies 104, as shown in FIG. 2B. In other embodiments, the width 210 may be chosen to be smaller so as to only overlap with the first semiconductor dies 102.

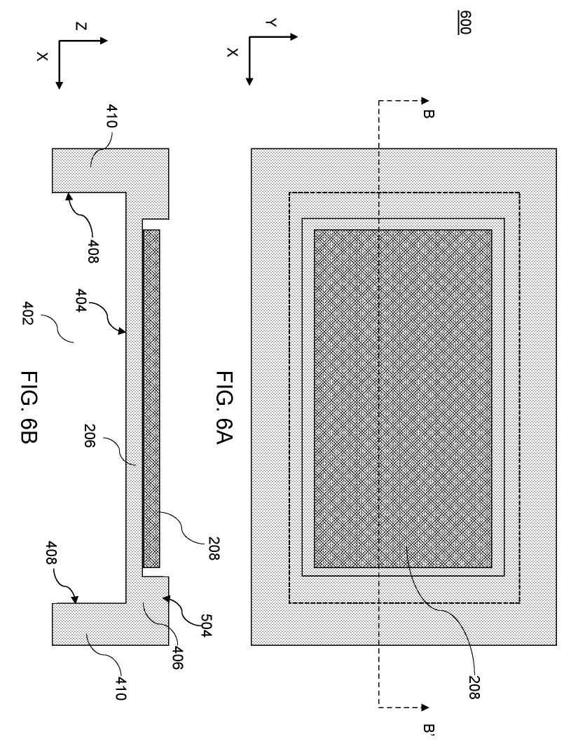

The spatial location, shape, and width of the multi-layer structure 204 may be configured in various ways, as described in greater detail with reference to FIGS. 7A to 15B, below. In this way, the package lid 120b may be configured to have a top portion 406 of the first material 206 having a spatially varying thermal conductivity that is greater in a first region (e.g., corresponding to a location of the multi-layer structure 204) than in a second region (e.g., corresponding to a location of a region in which the multi-layer structure 204 is absent). Further, depending on the overall thermal characteristics of the semiconductor package structure 200b, at least a portion of the first region (i.e., the high-conductivity multi-layer structure 204) may be positioned to be overlapping with a location of at least one semiconductor die (102, 104) in a plan view.

In addition to dissipating heat, the package lid 120b may also be configured to have advantageous structural properties. In this regard, the package lid 120b may provide structural stability to the semiconductor package structure 200b. For example, during thermal cycling, the package lid 120b may be configured to reduce or mitigate structural deformations including warping, cracking, interface delamination, etc., that may otherwise be caused due different coefficients of thermal expansion of the various materials of the semiconductor package structure 200b. For example, the package substrate 110 may have a coefficient of thermal expansion (CTE) of approximately 14.5 ppm/ °C whereas copper (as used in a package lid such as 120a) has a coefficient of thermal expansion that is approximately 17 ppm/ °C. The discrepancy between the coefficient of thermal expansion of the package substrate 110 and, for example, a copper package lid 120a may lead to significant warpage of the semiconductor package structure 200a.

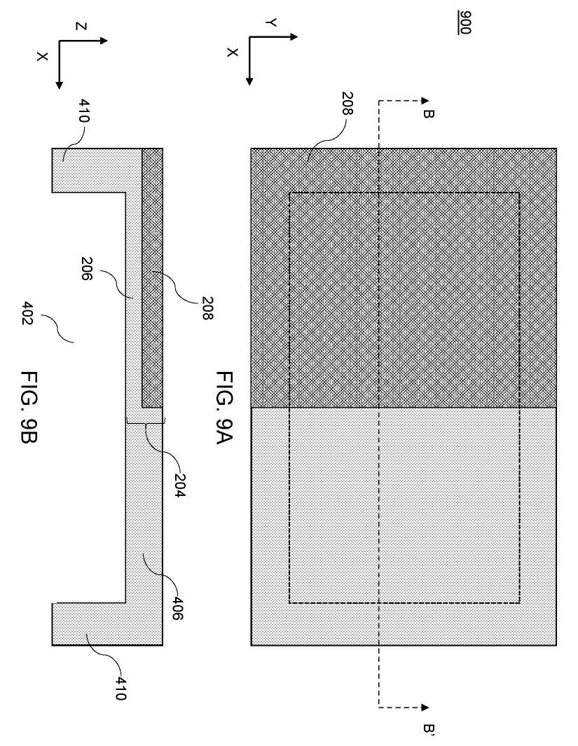

In contrast, the embodiment package lid 120b that includes the multi-layer structure 204 may be configured to have an effective coefficient of thermal expansion that is closer to that of the package substrate 110. In this regard, the second material 208 may include a silver/diamond composite that has a coefficient of thermal expansion that is in a range from approximately 5 ppm/ °C to approximately 10 ppm/ °C, which is significantly smaller than the coefficient of thermal expansion of copper (e.g., 17 ppm/ °C). Thus, as with the thermal conductivity, the effective coefficient of thermal expansion of the package lid 120b may be adjusted based on the size and shape of the placement of the second material 208 relative to the first material 206. In certain embodiments, the effective thermal conductivity of the package lid 120b may be a weighted average of the thermal conductivities of the first material 206 and the second material 208 based on relative volumes of the first material 206 and the second material 208, respectively. In certain embodiments, the package lid 120b may have an effective coefficient of thermal expansion that is in a range from approximately 14.5 ppm/ °C to approximately 17 ppm/ °C. Further, the package lid 120b may have a spatially varying coefficient of thermal expansion including a second material 208 that includes two or more spatially separated portions, as described in greater detail with reference to FIGS. 10A to 11B, 14A and 14B below.

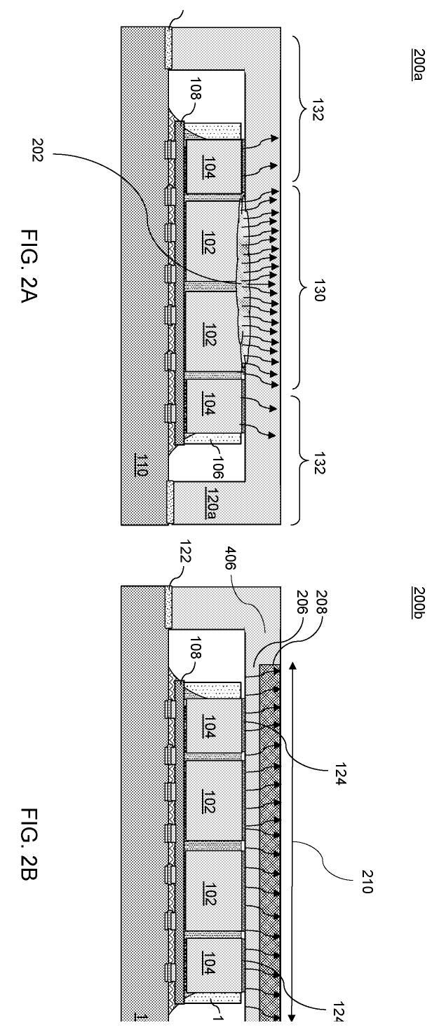

FIGS. 3A to 6B illustrate various intermediate structures that may be used in the formation of a package lid 700 (e.g., see FIGS. 7A and 7B), according to various embodiments. The intermediate structure 300 of FIGS. 3A and 3B may include a slab 302 of a first material 206 that may be used in the formation of a package lid 700. FIG. 3A is a top view of the intermediate structure 300 and FIG. 3B is a cross-sectional view, defined by the vertical plane indicated by the line B – B’ in FIG. 3A, of the intermediate structure 300. The first material 206 may be a metal or a metal alloy. For example, the first material 206 may be copper, aluminum, etc. Various types of metal or metal alloys are contemplated within the scope of this disclosure.

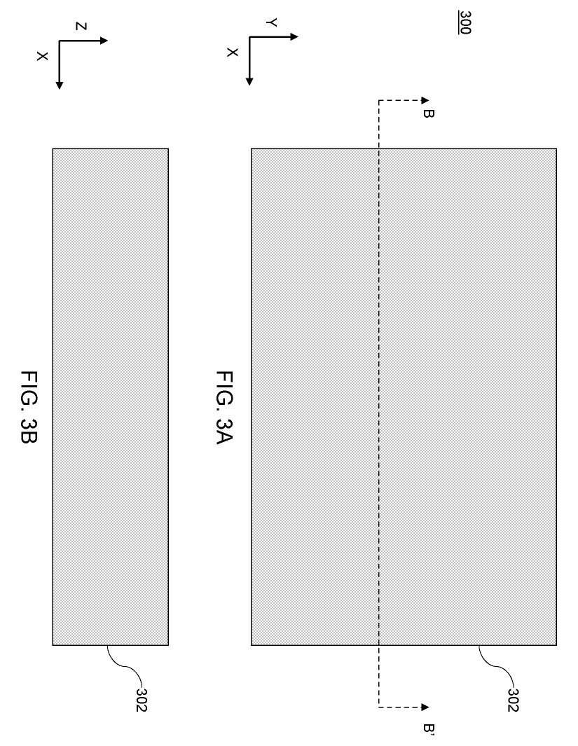

FIG. 4A is a top view of a further intermediate structure 400 that may be used in the formation of a package lid 700, and FIG. 4B is a vertical cross-sectional view of the intermediate structure 400 of FIG. 4A, according to various embodiments. The vertical cross-sectional view of FIG. 4B is defined by the vertical plane indicated by the line B – B’ in FIG. 4A. The intermediate structure 400 of FIGS. 4A and 4B may be generated from the intermediate structure 300 of FIGS. 3A and 3B by forming an inner cavity 402 in the slab of the first material 206 (i.e., in the intermediate structure 300 of FIGS. 3A and 3B). The inner cavity 402 may be generated by using a milling process to remove a portion of the first material 206 from the intermediate structure 300. For example, a computer numerical control (CNC) milling process may be performed to generate the inner cavity 402.

As shown in FIGS. 4A and 4B, the inner cavity 402 may have a rectangular parallelepiped shape that may bounded by an internal surface 404 of a top portion 406 of the first material 206 and at least partially bounded by internal surfaces 408 of side structures 410. In this regard, the side structures 410 may include four solid walls that laterally bound the inner cavity 402. Alternatively, the side structures may include openings (not shown) that may form vent holes to allow moisture and vapors to escape the semiconductor package structure (e.g., see semiconductor package structure 200b of FIG. 2B) once the package lid (120b, 700) has been installed on a package substrate 110 to form a semiconductor package structure 200b. The inner cavity 402 may have various other shapes in other embodiments.

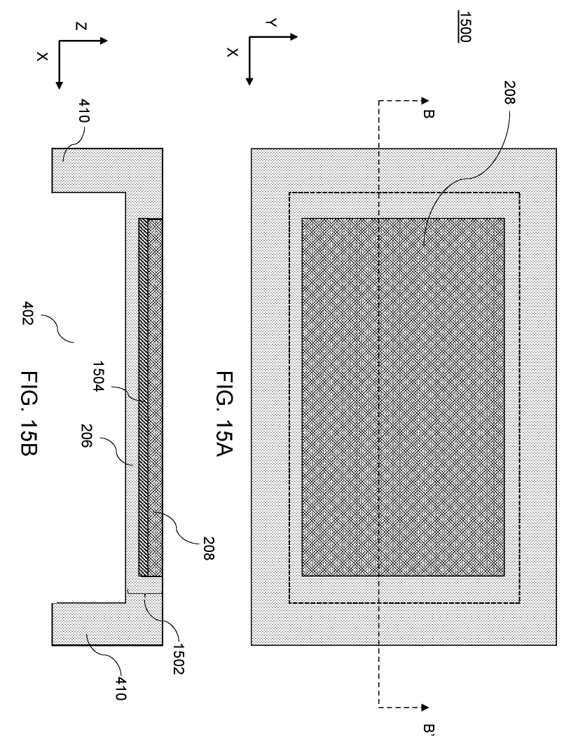

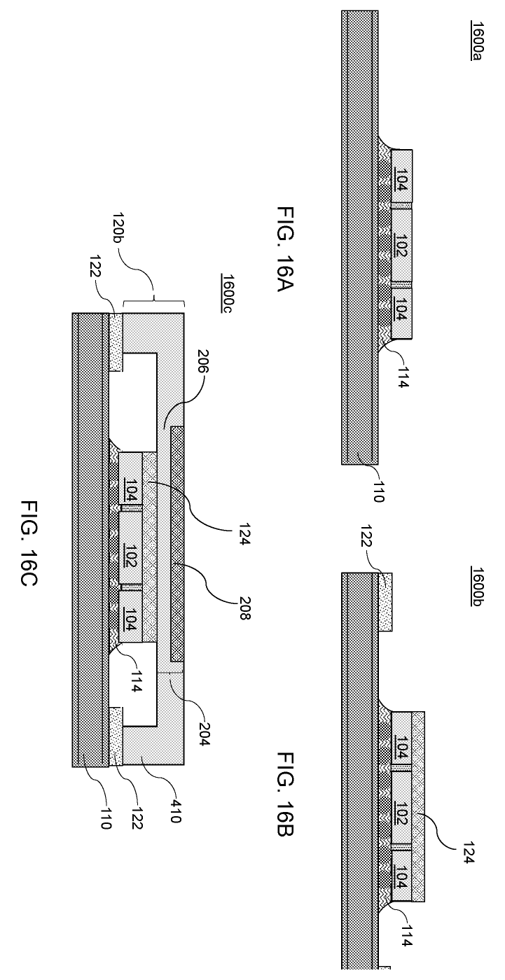

The inner cavity 402 may be configured to cover a semiconductor die (e.g., a first semiconductor die 102 or a second semiconductor die 104) and the of side structures 410 may be configured to attach to a package substrate 110 and to support the top portion 406 at a predetermined distance 412 above the package substrate 110. For example, the predetermined distance may be chosen based on a thickness of the semiconductor die (102, 104) and other components of the semiconductor package structure 200b (e.g., see FIG. 2B). For example, the semiconductor package structure 200b may include an interposer 108, or in other embodiments (e.g., see FIG. 16E) the interposer 108 may be omitted. The predetermined distance 412 may further allow a separation between a top surface of the semiconductor die (102, 104) and the internal surface 404 of the top portion 406 to allow space for a layer of a thermal interface material 124 (e.g., see FIG. 2B).

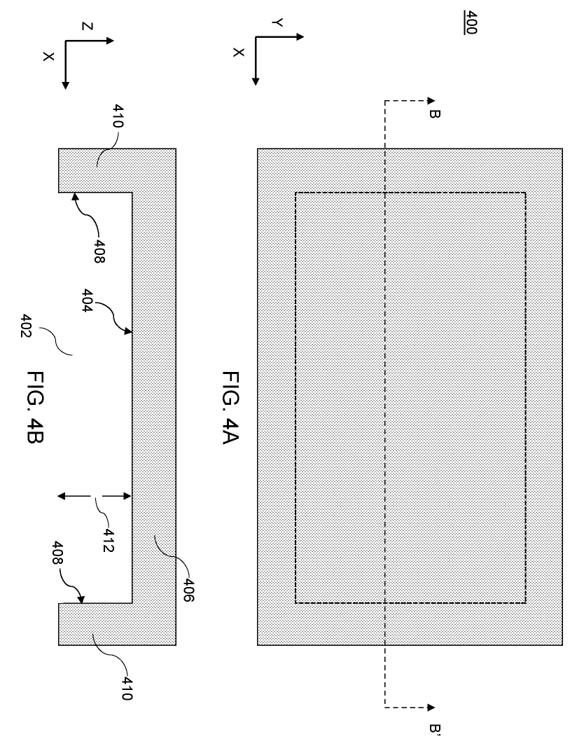

FIG. 5A is a top view of a further intermediate structure 500 that may be used in the formation of a package lid 700, and FIG. 5B is a vertical cross-sectional view of the intermediate structure 500 of FIG. 5A, according to various embodiments. The vertical cross-sectional view of FIG. 5B is defined by the vertical plane indicated by the line B – B’ in FIG. 5A. The intermediate structure 500 of FIGS. 5A and 5B may be generated from the intermediate structure 400 of FIGS. 4A and 4B by forming an outer cavity 502 in an external surface 504 of the top portion 406 of the first material 206. The outer cavity 502 may be generated by using a milling process to remove a further portion of the first material 206 from the intermediate structure 400 of FIGS. 4A and 4B. For example, a CNC milling process may be performed to generate the outer cavity 502. As shown in FIGS. 5A and 5B, the outer cavity 502 may have a rectangular parallelepiped shape that may bounded by various outer cavity surfaces 506. Other embodiments may include outer cavities 502 having various other shapes.

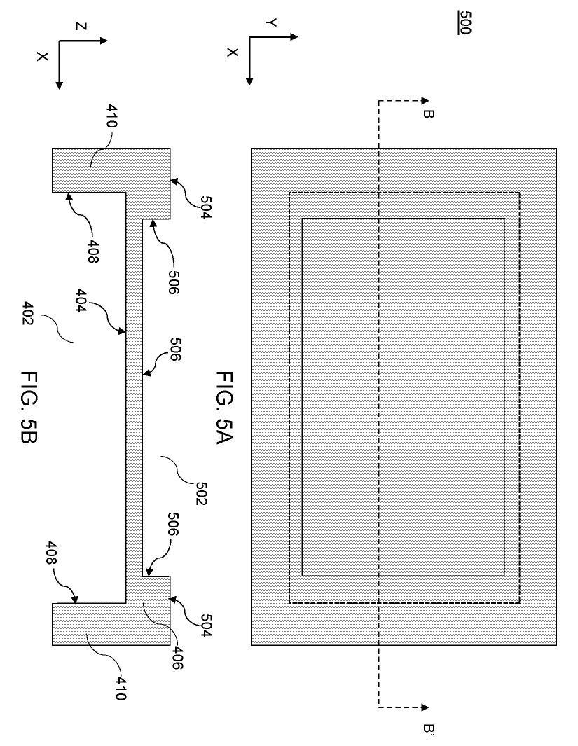

FIG. 6A is a top view of a further intermediate structure 600 that may be used in the formation of a package lid 700, and FIG. 6B is a vertical cross-sectional view of the intermediate structure 600 of FIG. 6A, according to various embodiments. The vertical cross-sectional view of FIG. 6B is defined by the vertical plane indicated by the line B – B’ in FIG. 6A. The intermediate structure 600 of FIGS. 6A and 6B may be generated from the intermediate structure 500 of FIGS. 5A and 5B by securing a second material 208 to the first material 206 (i.e., the material of the intermediate structure 500 of FIGS. 5A and 5B) within the outer cavity 502. For example, as described above, the second material 208 may be a metal/diamond composite in which diamond particles may be formed within a metal matrix. According to an embodiment, the second material 208 may be a silver/diamond, a copper/diamond, or an aluminum/diamond composite material.

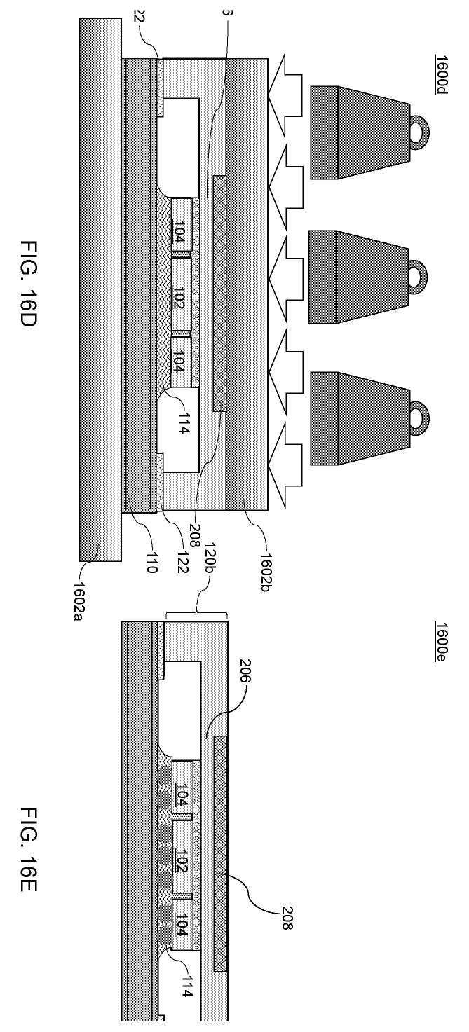

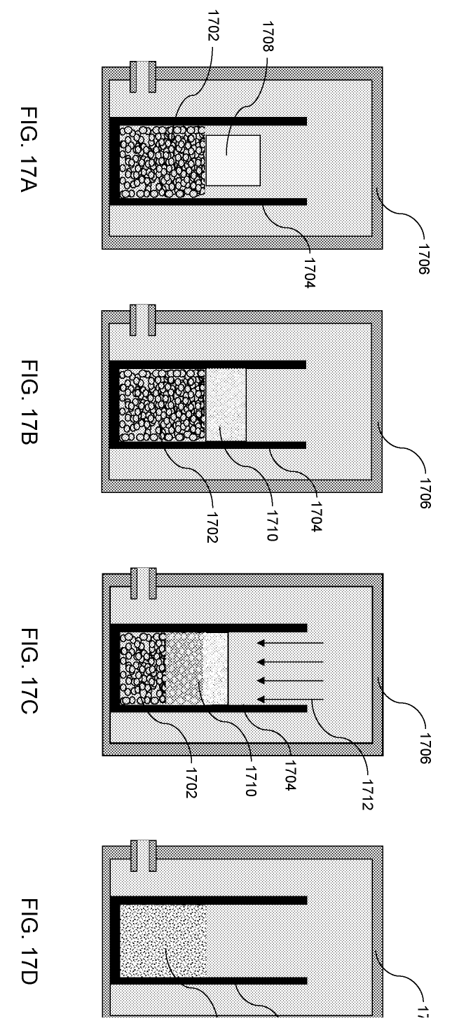

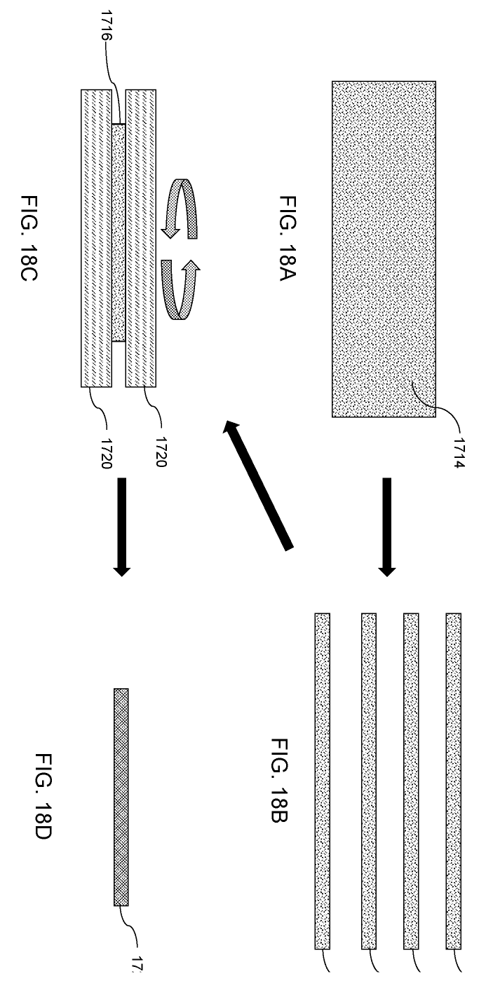

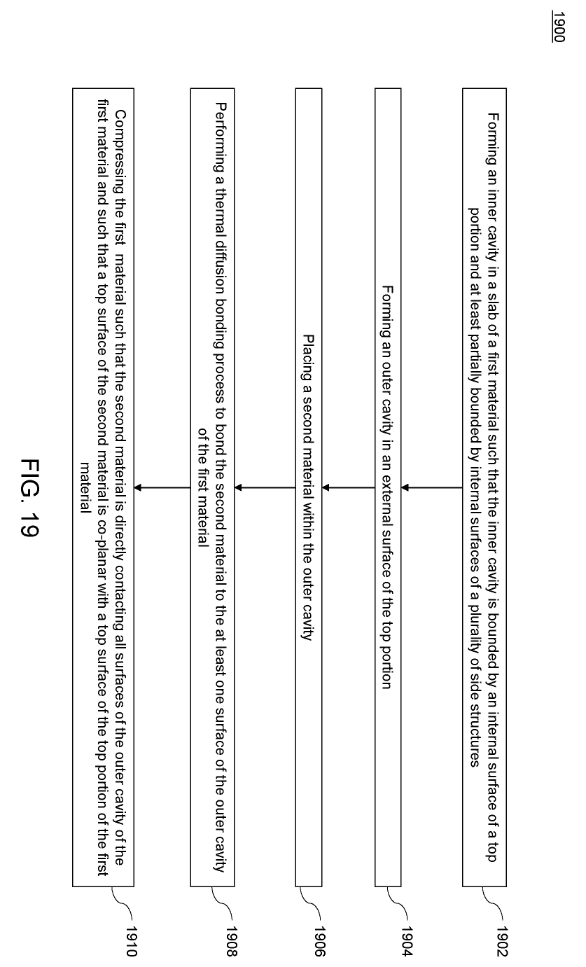

The second material 208 may be formed according to a processes described below with reference to FIGS. 17A to 18D. In this regard, the second material 208 may be formed as a bulk material (e.g., see FIG. 18A) that may be machined into slabs (e.g., see FIG. 18B) of various sizes. As shown in FIG. 6B, a slab of the second material 208 may be placed within the outer cavity 502 so as to be resting on one of the outer cavity surfaces 506. A bonding process may then be performed to thereby secure the second material 208 to at least one of the outer cavity surfaces 506. In various example embodiments, the second material 208 may be one of a silver/diamond, a copper/diamond, or an aluminum/diamond composite material and a thermal diffusion bonding process may be performed to bond the second material 208 to the at least one outer cavity surfaces 506 of the first material 206.

The thermal diffusion bonding process may be performed by applying a force (e.g., in a range from 1 N/mm2 to approximately 7 N/mm2) to the second material 208 at an elevated temperature (e.g., in range from 100 °C to 300 °C) for a certain time (e.g., a few minutes to a few hours). In an example embodiment, the first material 206 may be copper and the second material 208 may be a silver/diamond composite material having a thermal conductivity that is within a range from approximately 600 W/m·K to approximately 900 W/m·K. A stamping process may then be performed to ensure that the second material 208 may make close contact with all outer cavity surfaces 506, as described with reference to FIGS. 7A and 7B, below, and is not limited thereto.

FIG. 7A is a top view of a package lid 700 having a multi-layer structure 204, and FIG. 7B is a vertical cross-sectional view of the package lid 700 of FIG. 7A, according to various embodiments. The vertical cross-sectional view of FIG. 7B is defined by the vertical plane indicated by the line B – B’ in FIG. 7A. The package lid 700 of FIGS. 7A and 7B may be generated from the intermediate structure 600 of FIGS. 6A and 6B by performing a mechanical stamping operation. The stamping operation may be performed to compress the external surface 504 of the top portion 406 such that the top portion 406 deforms to make contact with the second material 208 such that the second material 208 is directly contacting all outer cavity surfaces 506 (e.g., see FIG. 5B). Further, the stamping operation may compress the top portion 406 of the first material 206 such that the external surface 504 of the top portion 406 is co-planar with a top surface 702 of the second material 208, as shown in FIGS. 7A and 7B.

Prior to performing the stamping operation, the second material 208 may have a thickness that is less than a depth of the outer cavity, as shown in FIG. 6B. Further, prior to performing the stamping operation, a length and width of the second material 208 may be chosen to be slightly less than both a corresponding length and width of the outer cavity 502. In this regard, the top portion 406 may deform laterally under the stamping operation. The degree to which the top portion 406 may deform laterally relative to a longitudinal compression (i.e., compression vertically in FIGS. 6B and 7B) may be characterized by the Poisson ratio ν, which is defined as a ratio of transverse strain ε₂ to longitudinal strain ε₁ given by ν= |ε_{2/}ε₁ |.

In this example embodiment (e.g., see FIGS. 7A and 7B), the top portion 406 and the first material 206 may be copper having a Poisson ratio equal to 0.34 and the second material 208 may be a silver/diamond composite material having a Poisson ratio in a range from approximately 0.24 to approximately 0.25. Based on the Poisson ratios of the top portion and the first material 206 and the second material 208, a length, width, and thickness of the top portion 406 and first material 206 may be configured such that that stamping process compresses the top portion 406 of the first material 206 to have the configuration described above (i.e., tight contact between the first material 206 and the second material 208 and a top surface 702 of the second material 208 that is level or co-planar with the external surface 504 of the top portion 406).

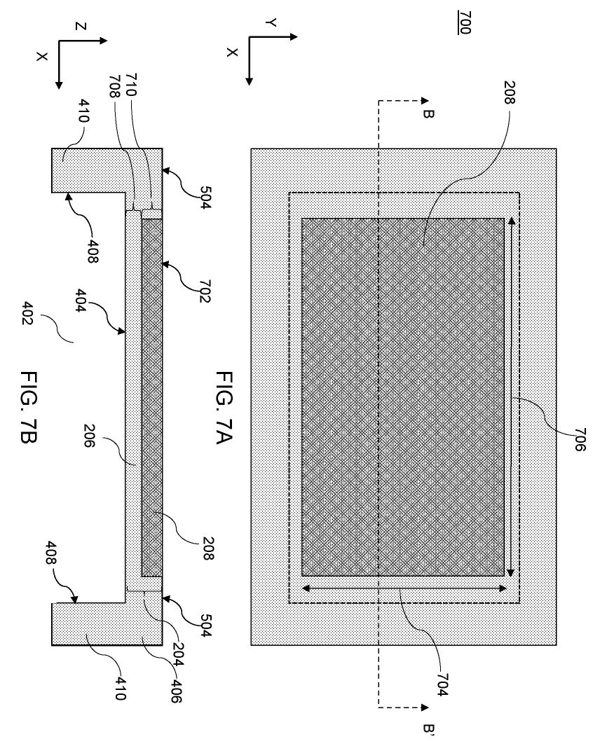

In an example embodiment, the second material 208 may have a width 704 and a length 706 that are each in a range from approximately 2 mm to approximately 30 mm. The multi-layer structure 204 may be configured such that the first material 206 may have a first thickness 708 and the second material 208 has a second thickness 710. The second thickness 710 may be greater than 0.2 mm and the first thickness 708 may greater than the second thickness 710. Other embodiments may include various other values for the width 704, length 706, first thickness 708, and second thickness 710. As shown in FIGS. 2B, 7A, and 7B, the second material 208 may be located in a central portion of the top portion 406 of the package lid (120b, 700). In other embodiments, however, the second material 208 may be distributed in various other ways, as described in greater detail with reference to FIGS. 8A to 15B, below.

FIGS. 8A to 15B illustrate embodiment package lids 800 to 1500 having respective configurations of the multi-layer structure 204, according to various embodiments. Each of the embodiment package lids 800 to 1500 may include a top portion 406 having a spatially varying thermal conductivity that is greater in a first region than in a second region. The first region may correspond to a location of the multi-layer structure 204 that includes a second material 208 supported over a layer of the first material 206. The second region may be an area of the top portion 406 that does not include the multi-layer structure 204. As describe above, the second material 208 may have a greater thermal conductivity than the first material 206. For example, the second material may be a metal/diamond composite material having a thermal conductivity that is within a first range from approximately 600 W/m·K to approximately 900 W/m·K, while the first material 206 may be copper having a thermal conductivity that is approximately 391 W/m·K.

Thus, the first region (e.g., corresponding to the multi-layer structure 204) may have a thermal conductivity that may be intermediate between the thermal conductivity of the first material 206 and that of the second material 208. For example, the thermal conductivity of the first region may be in a range from approximately 391 W/m·K to approximately 900 W/m·K, while the thermal conductivity of the second region (i.e., any region of the top portion 406 excluding the first region) may have a thermal conductivity of the first material 206 (e.g., in embodiments in which the first material 206 is copper, the thermal conductivity may be approximately 391 W/m·K). The thermal conductivity in the multi-layer structure 204 may be given by a volumetric weighted average determined by the relative volumes of the first material 206 and the second material 208.

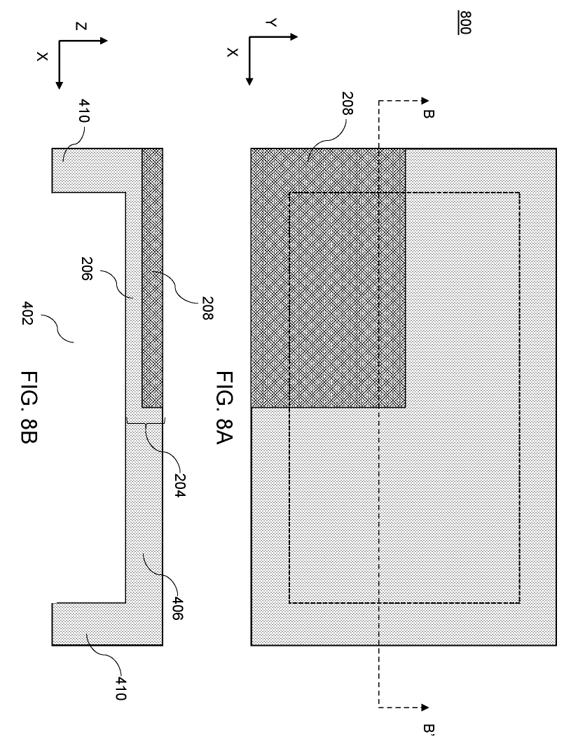

FIGS. 8A and 8B illustrate an embodiment package lid 800 in which the second material 208 portion may be located proximate to a corner of the top portion 406 of package lid 800 and FIGS. 9A and 9B illustrate an embodiment package lid 900 in which the second material 208 may be located proximate to one side of the top portion 406 of package lid 900, according to various embodiments. FIGS. 8A and 9A provide top views, and the vertical cross-sectional views of FIGS. 8B and 9B are defined by the vertical planes indicated by the lines B – B’ in FIGS. 8A and 9A, respectively. The configuration of FIGS. 8A and 8B may be used in a semiconductor package structure in which heat generating devices produce a greater heat flux near the corner corresponding to the placement of the multi-layer structure 204. Similarly, configuration of FIGS. 9A and 9B may be used in a semiconductor package structure in which heat generating devices produce a greater heat flux near the side corresponding to the placement of the multi-layer structure 204.

FIG. 10A is a top view of a further package lid 1000 having a multi-layer structure 204 including two spatially separated portions (204a, 204b), and FIG. 10B is a vertical cross-sectional view of the package lid 1000 of FIG. 10A, according to various embodiments. The vertical cross-sectional view of FIG. 10B is defined by the vertical plane indicated by the line B – B’ in FIG. 10A. The multi-layer structure may include a first multi-layer structure portion 204a and second multi-layer structure portion 204b (e.g., see FIG. 10B). As shown, the first multi-layer structure portion 204a may include a first portion 208a of the second material 208 and the second multi-layer structure portion 204b may include a second portion 208b of the second material 208. In each of the first multi-layer structure portion 204a and the second multi-layer structure portion 204b the respective second material (208a, 208b) is formed over a layer of the first material 206.

As with previous embodiments, the first material 206 may be a metal such as copper, aluminum, etc., and the second material (208a, 208b) may be a metal/diamond composite material such as silver/diamond, a copper/diamond, or an aluminum/diamond, etc. Various other combinations of material may be used in other embodiments within the contemplated scope of this disclosure. The configuration of FIGS. 10A and 10B may be used in a semiconductor package structure in which heat generating devices produce a greater heat flux near the two regions corresponding to the placement of the first multi-layer structure portion 204a and second multi-layer structure portion 204b.

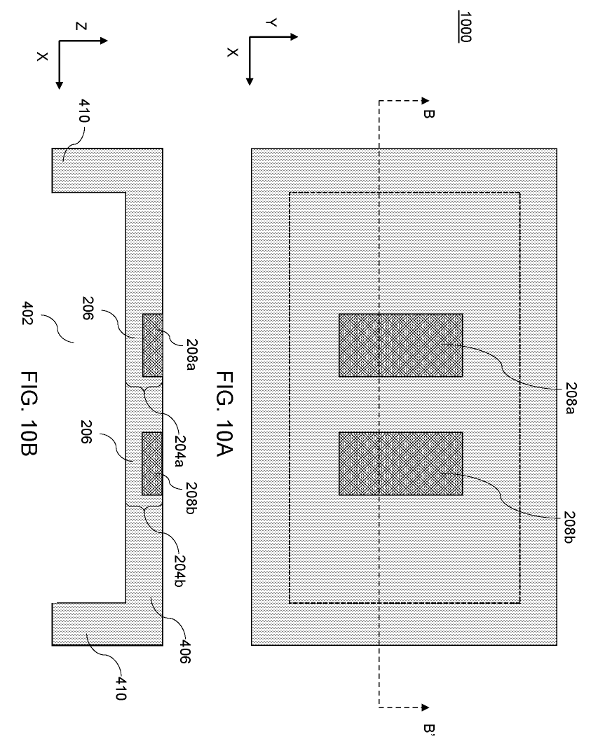

FIG. 11A is a top view of a further package lid 1100 having a multi-layer structure 204 including four spatially separated portions (only 204a, 204b shown in FIG. 11B), and FIG. 11B is a vertical cross-sectional view of the package lid 1100 of FIG. 11A, according to various embodiments. The vertical cross-sectional view of FIG. 11B is defined by the vertical plane indicated by the line B – B’ in FIG. 11A. The multi-layer structure 204 may include a first multi-layer structure portion 204a, a second multi-layer structure portion 204b, a third multi-layer structure portion (204c, not shown in FIG. 11B), and a fourth multi-layer structure portion (204d, not shown in FIG. 11B). As shown, the first multi-layer structure portion 204a may include a first portion 208a of the second material 208, the second multi-layer structure portion 204b may include a second portion 208b of the second material 208, the third multi-layer structure portion (204c, not shown in FIG. 11B) may include a third portion 208c of the second material 208, and the fourth multi-layer structure portion (204d, not shown in FIG. 11B) may include a fourth portion 208d of the second material 208.

In each of the first multi-layer structure portion 204a, the second multi-layer structure portion 204b, the third multi-layer structure portion (204c, not shown in FIG. 11B), and the fourth multi-layer structure portion (204d, not shown in FIG. 11B), the respective second material (208a, 208b, 208c, 208d) is formed over a layer of the first material 206. As with previous embodiments, the first material 206 may be a metal such as copper, aluminum, etc., and the second material (208a, 208b, 208c, 208d) may be a metal/diamond composite material such as silver/diamond, a copper/diamond, or an aluminum/diamond, etc. Various other combinations of material may be used in other embodiments within the contemplated scope of this disclosure. The configuration of FIGS. 11A and 11B may be used in a semiconductor package structure in which heat generating devices produce a greater heat flux near the four regions corresponding to the placement of the first multi-layer structure portion 204a, the second multi-layer structure portion 204b, the third multi-layer structure portion (204c, not shown in FIG. 11B), and the fourth multi-layer structure portion (204d, not shown in FIG. 11B).

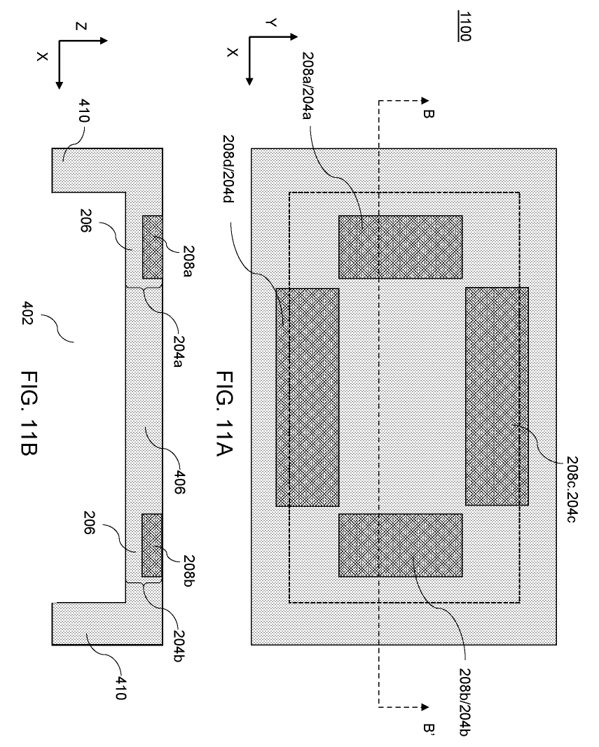

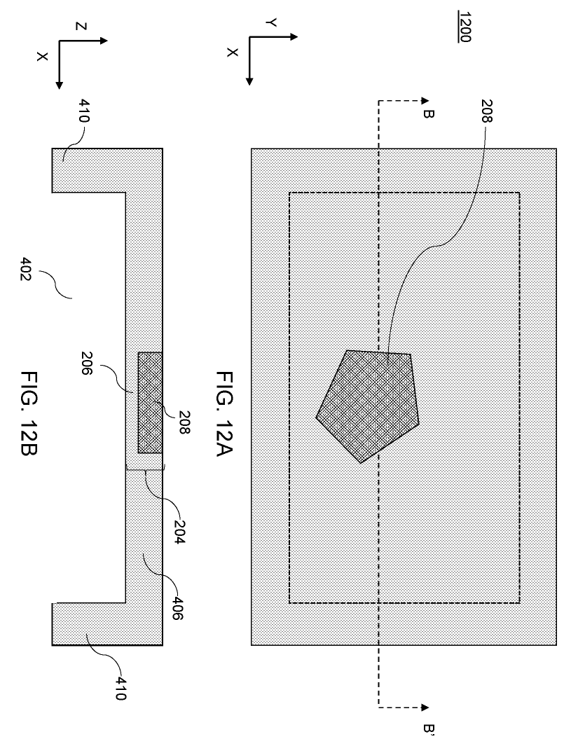

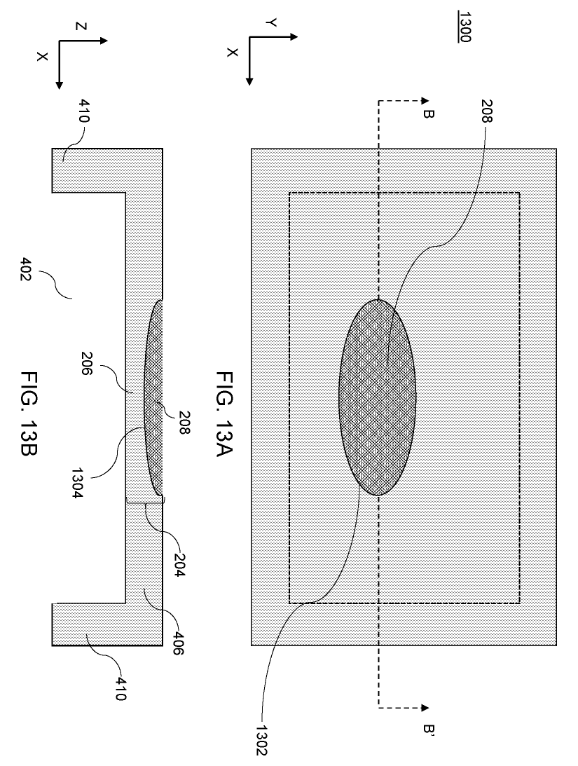

FIG. 12A is a top view of a further package lid 1200 having a multi-layer structure 204 including a single second material 208 portion having a polygon shape, FIG. 12B is a vertical cross-sectional view of the package lid of FIG. 12A, according to various embodiments. The vertical cross-sectional view of FIG. 12B is defined by the vertical plane indicated by the line B – B’ in FIG. 12A. Other embodiments may include a multi-layer structures in which the second material 208 is formed in various shapes and sizes. In this way, package lids may be configured to have a variety of spatially varying thermal conductivity profiles to provide efficient extraction of thermal energy form spatially varying heat sources. All of the above example embodiments include multi-layer structures 204 including a second material 208 having a rectangular or polygon shape. The shape of the second material 208, however, need not be limited to rectangular or polygon shaped regions, as described in greater detail with reference to FIGS. 13A to 14B, below.

FIG. 13A is a top view of a further package lid 1300 having a multi-layer 204 structure including a single second material 208 portion having a curved shape, and FIG. 13B is a vertical cross-sectional view of the package lid of FIG. 13A, according to various embodiments. The vertical cross-sectional view of FIG. 13B is defined by the vertical plane indicated by the line B – B’ in FIG. 13A. In this example embodiment, the second material 208 may have a first surface 1302 in the plane of FIG. 13A that is a smooth curve forming an oval shape. Further, as shown in FIG. 13B, the second material 208 may similarly have a second surface 1304 (i.e., a bottom surface) that is also a smooth shape.

The package lid 1300 may be formed using processes similar to those described above with reference to FIGS. 3A to 7B. In this regard, an outer cavity 502 may be formed (e.g., see FIG. 5B) and the second material 208 may be formed within the outer cavity 502 using processes described above with reference to FIGS. 6A to 7B. The shape of the second surface 1304 in the package lid 1300 may correspond to a shape of the outer cavity 502. In this regard, the outer cavity 502 may be formed using a milling process (e.g., a CNC milling process) that may generate various shapes, such as the smooth shape of second surface 1304. The size, shape, and placement of the second material 208 may be configured to optimize heat extraction from the package lid. For example, in certain embodiments, it may be advantageous to have a second material 208 portion having a smooth shape with smooth surfaces such as the first surface 1302 and the second surface to avoid local hot spots that may otherwise occur with surfaces having sharp corners.

FIG. 14A is a top view of a further package lid 1400 having a multi-layer structure 204 including three spatially separated portions each having a curved shape, and FIG. 14B is a vertical cross-sectional view of the package lid of FIG. 14A, according to various embodiments. The vertical cross-sectional view of FIG. 14B is defined by the vertical plane indicated by the line B – B’ in FIG. 14A. As shown, the second material 208 may include a first portion 208a, a second portion 208b, and a third portion 208c, which each may respectively include a first surface (1402a, 1402b, 1402c) and a second surface (1404a, 1404b, 1404c). As with the embodiment package lid 1300 of FIGS. 13A and 13B, each of the first surface (1402a, 1402b, 1402c) and the second surface (1404a, 1404b, 1404c) may be a smooth curved surface. Other embodiments may include various other sizes, shapes, and placements of the second material 208 that may be configured to optimize heat extraction based on a spatially dependent profile of heat sources. In addition to straight and curved surfaces, various other embodiments may include a second material 208 including irregular or rough surfaces (not shown).

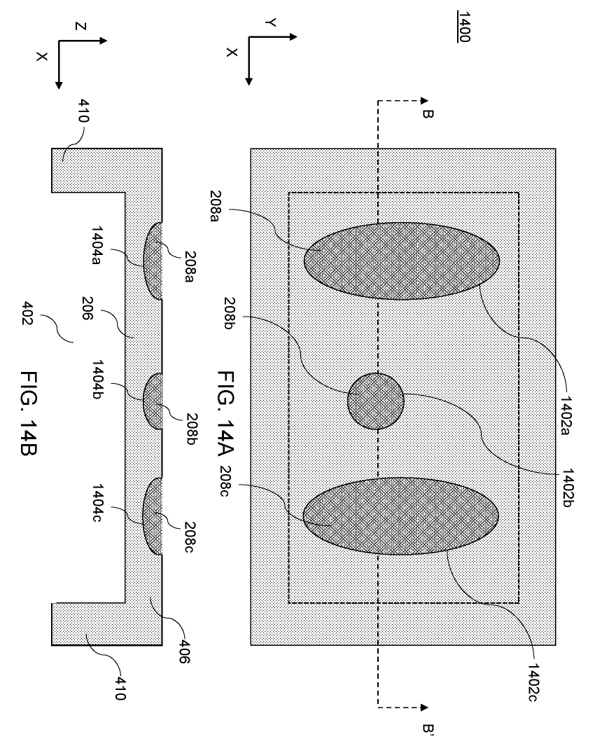

FIG. 15A is a top view of a further package lid 1500 having a tri-layer (tri-material) structure 1502, and FIG. 15B is a vertical cross-sectional view of the package lid of FIG. 15A, according to various embodiments. The vertical cross-sectional view of FIG. 15B is defined by the vertical plane indicated by the line B – B’ in FIG. 15A. The tri-layer structure 1502 may include a first material 206 having a first thermal conductivity, a second material 208 having a second thermal conductivity, and a third material 1504 having a third thermal conductivity. In various embodiments, the first material 206 may be a metal such as copper, aluminum, etc., and the second material 208 and the third material 1504 may each be a metal/diamond composite. For example, in one embodiment, the second material 208 may be silver/diamond composite and the third material 1504 may be one of a copper/diamond composite or an aluminum/diamond composite. The first material 206, the second material 208, and the third material 1504 may further be selected to provide a composite CTE that is similar or matches the CTE of the package substrate 110 to mitigate against warpage.

Other embodiments may include various other material combinations including additional material layers. Still further embodiments may include a material having a thermal conductivity that has a gradient (i.e., spatially varying) profile. As with other embodiments described above, the tri-layer structure 1502 may include two or more spatially separated portions. Further, the various spatially separated portions may include different or the same materials and corresponding thermal conductivities. For example, in an embodiment having two spatially separated portions (e.g., see FIGS. 10A and 10B), one of the spatially separated portions may include a first material 206 (e.g., a silver/diamond composite) and the other spatially separated portion may include a second material (e.g., a copper/diamond composite), etc.

FIGS. 16A to 16D are vertical cross-sectional views of respective intermediate structures 1600a to 1600d that may be used in the formation of a semiconductor package structure 1600e, and FIG. 16E is a vertical cross-sectional view of the resulting semiconductor package structure 1600e, according to various embodiments. As shown in FIG. 16A, a first intermediate structure 1600a may include a plurality of semiconductor dies (102, 104) that may be attached and electrically coupled to a package substrate 110. A first underfill material portion 114 may be provided between a top surface of the package substrate 110 and bottom surfaces of the plurality of semiconductor dies (102, 104). A further intermediate structure 1600b may be formed by forming an adhesive 122 on a top surface of the package substrate 110 and forming a thermal interface material (TIM) layer 124 over top surfaces of the plurality of semiconductor dies (102, 104).

A further intermediate structure 1600c may then be formed by placing a package lid 120b over the intermediate structure 1600b of FIG. 16B. As shown, the package lid 120b may be placed so that side structures 410 of the package lid 120 are in contact with the adhesive so that the package lid 120b may bonded to the package substrate 110. The intermediate structure 1600c of FIG. 16C may then be placed within a clamping structure having a lower clamping structure 1602a and an upper clamping structure 1602b, as shown in FIG. 16D. The intermediate structure 1600d may then be subjected to a hot clamping process in which the intermediate structure 1600d is heated under pressure. The pressure and heat may cause the adhesive 122 to spread and to cure thereby bonding the package lid 120b to the package substrate 110. After application of the hot clamping process, the resulting semiconductor package structure 1600e may be removed from the clamping structure (1602a, 1602b) as shown in FIG. 16E.

FIGS. 17A to 17D are vertical cross-sectional views of an apparatus in various configurations during a gas pressure infiltration process of forming a metal/diamond composite material 1714, according to various embodiments. As shown in FIG. 17A, for example, a diamond preform 1702 (e.g., diamond powder) may be placed in a crucible 1704 within a vacuum furnace 1706. A volume of solid metal 1708 may also be placed within the crucible 1704 on top of the diamond preform 1702. The furnace 1706 may then be evacuated and may be heated under vacuum to a temperature sufficient to melt the metal thereby forming a molten metal 1710, as shown in FIG. 17B. An inert high pressure gas 1712 (e.g., argon) may then be introduced into the furnace 1706 at elevated temperature, as shown in FIG. 17C. The high pressure gas 1712 may then cause the molten metal 1710 to infiltrate the diamond preform 1702. The temperature and pressure may then be reduced once the molten metal 1710 has fully infiltrated the diamond preform 1702. Upon cooling, the metal may then re-solidify to form a metal matrix of the metal/diamond composite material 1714, as shown in FIG. 17D.

FIGS. 18A to 18D illustrate various further processing operations that may be performed on the metal/diamond composite material 1714 formed by the gas pressure infiltration process (described above with reference to FIGS. 17A to 17D), according to various embodiments. After extraction from the crucible 1704 of the vacuum furnace, the composite material 1714 may form a bulk solid material that may have properties similar to that of bulk metal. In this regard, the composite material 1714 may be malleable and may be machinable. As such, the composite material 1714 may be cut into various sections (1716a, 1716b, 1716c, 1716d) as shown, for example, in FIG. 18B. Each of the sections (1716a, 1716b, 1716c, 1716d) may be further processed by further cutting, polishing, grinding, etc. For example, as shown in FIG. 18C, a section 1716 may be subjected to a grinding/polishing process in a grinding apparatus 1720. In some embodiments, the polished section 1716 may be plated with nickel, chromium, etc. to yield a final composite material section 1722 (also referred to as second material 208), as shown in FIG. 18D. The final composite material section 1722 may have a thickness in a range from approximately 0.2 mm to approximately 35 mm.

FIG. 19 is a flowchart illustrating operations of a method 1900 of forming a package lid (120b, 700, 800, 900, 1000, 1200, 1300, 1400, 1500) for a semiconductor package structure (200b, 1600e), according to various embodiments. In operation 1902, the method 1900 may include forming an inner cavity 402 in a slab 302 of a first material 206 such that the inner cavity 402 is bounded by an internal surface 404 of a top portion 406 and at least partially bounded by internal surfaces 408 of a plurality of side structures 410. The inner cavity 402 may be configured to cover a semiconductor die (102, 104) and the plurality of side structures 410 may be configured to attach to a package substrate 110 and to support the top portion 406 at a predetermined distance 412 above the package substrate 110.

In operation 1904, the method 1900 may include forming an outer cavity 502 in an external surface 504 of the top portion 406. The method 1900 may further include securing a second material 208 to the first material 206 within the outer cavity 502 so that the second material 208 is bonded to at least one surface of the outer cavity 502. In this regard, in operation 1906, the method 1900 may include placing the second material 208 within the outer cavity 502 followed by performing a bonding process to secure the second material 208 to the first material 206 within the outer cavity 502. For example, the bonding process may include a thermal diffusion bonding process. Thus, in operation 1908, the method 1900 may include performing a thermal diffusion bonding process to bond the second material 208 to the at least one surface of the outer cavity 502 of the first material 206.

In operation 1910, the method 1900 may include compressing the first material 206 (e.g., compressing the top portion 406 of the first material 206) such that the second material 208 is directly contacting all surfaces of the outer cavity 502 of the first material 206, and such that a top surface 702 of the second material 208 is co-planar with a top surface 504 of the top portion 406 of the first material 206. The second material 208 may be chosen to have a thermal conductivity that is within a range from approximately 600 W/m·K to approximately 900 W/m·K. For example, in various embodiments, the second material 208 may be one of a silver/diamond, a copper/diamond, or an aluminum/diamond composite material. The first material 206 may be a metal such as copper, aluminum, etc.

Referring to all drawings and according to various embodiments of the present disclosure, a semiconductor package structure (200b, 1600e) is provided. The semiconductor package structure (200b, 1600e) may include a package substrate 110, a semiconductor die (102, 104) coupled to the package substrate 110, and a package lid (120b, 700, 800, 900, 1000, 1200, 1300, 1400, 1500) attached to the package substrate 110 and covering the semiconductor die (102, 104). The package lid (120b, 700, 800, 900, 1000, 1200, 1300, 1400, 1500) may include a first region including a first material 206 having a first thermal conductivity value and a second material 208 having a second thermal conductivity value; and a second region including the first material 206. At least a portion of the first region (204, 1502) may be positioned to be overlapping with a location of the semiconductor die (102, 104) in a plan view (e.g., see FIGS. 2B an 16E). The package lid (120b, 700, 800, 900, 1000, 1200, 1300, 1400, 1500) may include a top portion 406 having a spatially varying thermal conductivity that is greater in a first region (e.g., in a location of a multi-layer structure 204 or a tri-layer structure 1502) than in a second region (e.g., regions other than the multi-layer structure 204 or tri-layer structure 1502).

In certain embodiments, the second thermal conductivity may be within a first range from approximately 600 W/m·K to approximately 900 W/m·K. The second material 208 may also have a coefficient of thermal expansion that is in a second range from approximately 5 ppm/ °C to approximately 10 ppm/ °C. For example, the second material 208 may include a metal/diamond composite material, such as a silver/diamond, a copper/diamond, or an aluminum/diamond composite material. In various embodiments, the package lid (120b, 700, 800, 900, 1000, 1200, 1300, 1400, 1500) may have an effective coefficient of thermal expansion that is in a range from approximately 14.5 ppm/ °C to approximately 17 ppm/ °C. The first region (204, 1502) may be located in a central portion of the top portion 406 (e.g., see FIGS. 7A, 7B, 15Aand 15B). In other embodiments, first region 204 may be located proximate to a corner of the top portion 406 (e.g., see FIGS. 8A and 8B). In other embodiments, the first region 204 may include two or more spatially separated portions (208a, 208b, 208c, 208d).

In various embodiments, the first material 206 may include copper 206. The metal/diamond composite material layer 208 may have a width 704 and a length 706 that are each in a range from approximately 2 mm to approximately 30 mm and a second thickness 710 that is greater than 0.2 mm. The copper layer 206 may have a first thickness 708 that is greater than the second thickness 710.

According to a further embodiment, a package lid (120b, 700, 800, 900, 1000, 1200, 1300, 1400, 1500) for a semiconductor package structure (200b, 1600e) is provided. The package lid (120b, 700, 800, 900, 1000, 1200, 1300, 1400, 1500) may include a top portion 406 configured to cover a semiconductor die (102, 104), a plurality of side structures 410 configured to attach to a package substrate 110 and to support the top portion 406 at a predetermined distance 412 above the package substrate 110. The top portion 406 may include a multi-layer structure 204 including a first material 206 having a first thermal conductivity and a second material 208 having a second thermal conductivity. The second thermal conductivity may be within a range from approximately 600 W/m·K to approximately 900 W/m·K. The second material 208 may also have a coefficient of thermal expansion that is in a first range from approximately 5 ppm/ °C to approximately 10 ppm/ °C. The package lid (120b, 700, 800, 900, 1000, 1200, 1300, 1400, 1500) may also have an effective coefficient of thermal expansion that is in a second range from approximately 14.5 ppm/ °C to approximately 17 ppm/ °C. In various embodiments, the second material 208 may have a silver/diamond, a copper/diamond, or an aluminum/diamond composite material.

Disclosed embodiments may provide advantages by providing a package lid having a spatially varying thermal conductivity that is greater in certain regions corresponding to regions having increased heat flux. Certain embodiments may include a multi-layer structure that incorporates a metal/diamond composite material supported by a copper layer. The diamond/metal layer may have thermal conductivity that is range from approximately 600 W/m·K to approximately 900 W/m·K, which is considerably higher than that of copper which has a thermal conductivity of 391 W/m·K, and a coefficient of thermal expansion that is in a range from approximately 5 ppm/ °C to approximately 10 ppm/ °C, which is considerably less than that of copper which has a thermal expansion coefficient of 17 ppm/ °C. As such, embodiment package lids may exhibit increased heat removal efficiency and reduced thermal-expansion induced warpage and other deformations in contrast to package lids made of a single metal.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A semiconductor package structure, comprising:
a package substrate;
a semiconductor die coupled to the package substrate; and
a package lid attached to the package substrate and covering the semiconductor die, the package lid comprising:
a top portion comprising a multi-layer structure including a first material having a first thermal conductivity and a second material having a second thermal conductivity, wherein the second thermal conductivity is greater than the first thermal conductivity; and
a plurality of side structures configured to attach to the package substrate and to support the top portion at a predetermined distance above the package substrate.

2. The semiconductor package structure of claim 1, wherein at least a portion of the multi-layer structure is positioned to be overlapping with a location of the semiconductor die in a plan view.

3. The semiconductor package structure of claim 1, wherein the second thermal conductivity is within a range from approximately 600 W/m·K to approximately 900 W/m·K.

4. The semiconductor package structure of claim 3, wherein the second material comprises a coefficient of thermal expansion that is in a range from approximately 5 ppm/°C to approximately 10 ppm/°C.

5. The semiconductor package structure of claim 3, wherein the second material comprises a metal/diamond composite material.

6. The semiconductor package structure of claim 5, wherein the second material comprises a silver/diamond, a copper/diamond, or an aluminum/diamond composite material.

7. The semiconductor package structure of claim 1, wherein the package lid comprises an effective coefficient of thermal expansion that is in a range from approximately 14.5 ppm/°C to approximately 17 ppm/°C.

8. A semiconductor package structure, comprising:
a package substrate;
a semiconductor die coupled to the package substrate; and
a package lid attached to the package substrate and covering the semiconductor die, the package lid comprising:
a top portion comprising a multi-layer structure including a first material and a second material, wherein the second material comprises a metal/diamond composite material having a thermal conductivity within a range from approximately 600 W/m·K to approximately 900 W/m·K; and
a plurality of side structures configured to attach to the package substrate and to support the top portion at a predetermined distance above the package substrate.

9. The semiconductor package structure of claim 8, wherein the multi-layer structure is located proximate to a corner of the top portion.

10. The semiconductor package structure of claim 8, wherein the second material comprises two or more spatially separated portions.

11. The semiconductor package structure of claim 8, wherein the first material comprises copper.

12. The semiconductor package structure of claim 11, wherein the second material comprises a metal/diamond composite material layer having a width and a length that are each in a range from approximately 2 mm to approximately 30 mm and a thickness that is greater than 0.2 mm.

13. The semiconductor package structure of claim 12, wherein the first material has a first thickness that is greater than the thickness of the second material.

14. .A semiconductor package structure, comprising:
a package substrate;
a semiconductor die coupled to the package substrate; and
a package lid attached to the package substrate and covering the semiconductor die, the package lid comprising:
a top portion comprising a multi-layer structure including a first material having a first thermal conductivity and a second material having a second thermal conductivity greater than the first thermal conductivity, wherein the package lid has an effective coefficient of thermal expansion in a range from approximately 14.5 ppm/°C to approximately 17 ppm/°C; and
a plurality of side structures configured to attach to the package substrate and to support the top portion at a predetermined distance above the package substrate.

15. The semiconductor package structure of claim 14, further comprising a heat sink provided on an upper surface of the package lid.

16. The semiconductor package structure of claim 14, wherein the plurality of side structures comprises four solid walls that laterally bound an inner cavity of the package lid.

17. The semiconductor package structure of claim 14, wherein the package lid is attached to the package substrate with a thermally-conductive adhesive.

18. The semiconductor package structure of claim 14, wherein the top portion has a spatially varying thermal conductivity that is greater in a first region corresponding to a location of the multi-layer structure than in a second region where the multi-layer structure is absent.

19. The semiconductor package structure of claim 14, wherein the second material has a first surface having a curved shape or a polygon shape.

20. The semiconductor package structure of claim 14, wherein the semiconductor die comprises a three-dimensional integrated circuit device, a system-on-chip device, or a system-on-integrated-circuit device.
